(19) United States
(12) Patent Application Publication
(10) Pub. No.: US 2025/0238064 A1
(43) Pub. Date: Jul. 24, 2025

(54) UNIVERSAL HIGH POWER/FAULT MANAGED POWER FRONT END

(71) Applicant: Cisco Technology, Inc., San Jose, CA (US)

(72) Inventors: George Allan Zimmerman, Manhattan Beach, CA (US); Chad M. Jones, Doylestown, OH (US); Jason Dewayne Potterf, Austin, TX (US); Joel Richard Goergen, Soulsbyville, CA (US); Elizabeth Kochuparambil, Morgan Hill, CA (US); Antonio Garza, Austin, TX (US); Matthew Stroud, Allen, TX (US)

(21) Appl. No.: 18/418,721

(22) Filed: Jan. 22, 2024

(51) Int. Cl. G06F 1/30; G01R 19/165; G01R 31/42

(52) U.S. Cl. CPC G06F 1/305; G01R 19/16547; G01R 31/42

(57) ABSTRACT

Methods for operating a power transmitter and a power receiver to enable selection of one of a plurality of power modes in a coordinated manner, as needed by a power receiver. The plurality of power modes may include fault managed power modes at different voltages, at least one non-fault managed power mode and an alternating current (AC) power mode.

### TECHNICAL FIELD

The present disclosure relates to techniques for providing power to devices.

### BACKGROUND

Fault Managed Power (FMP) techniques have typically been employed for power transmission on a cable over distances between a power transmitter and a power receiver, typically many meters. There are situations where it may be desirable to allow power receivers and power transmitters to negotiate the more suitable power to be delivered to a power receiver, in a more rapid manner than systems heretofore known.

### BRIEF DESCRIPTION OF THE DRAWINGS

FIG. 1A is a block diagram of a conventional AC power system.

FIG. 1B is a block diagram of a conventional DC-based power system.

FIG. 1C is a block diagram of a conventional FMP-based power system.

FIG. 2 is a block diagram of a power system with a universal front-end/power sourcing device that is configured to provide any of a variety of types of power to one or more power receivers, according to an example embodiment.

FIG. 3 is a block diagram of a power transmitter that forms a part of the universal front-end/power sourcing device shown in FIG. 2, according to an example embodiment.

FIG. 4 is a block diagram of a power receiver that forms a part of the power system shown in FIG. 2, according to an example embodiment.

FIGS. 5A and 5B illustrate a flow chart for operations of respective combination power transmitters that form a part of the universal front-end/power sourcing device of the power system shown in FIG. 2, according to an example embodiment.

FIGS. 6A and 6B illustrate a flow chart depicting operations of a power receiver that forms a part of the power system shown in FIG. 2, according to an example embodiment.

FIG. 7 is a timing diagram that depicts a signaling scheme that a power transmitter and power receiver may use to negotiate a power mode, according to example embodiment.

FIG. 8 is a flow chart depicting operations of a power transmitter in selecting a power mode type for delivering power to a power receiver, according to example embodiment.

FIG. 9 is a flow chart depicting operations of a power receiver in selecting a power mode type of power provided by a power transmitter, according to an example embodiment.

### DESCRIPTION OF EXAMPLE EMBODIMENTS

### Overview

In one form, a method is provided that is performed by a power receiver. The method includes upon powering up or upon power reset, determining a voltage type associated with power received at the power receiver from a power transmitter. Depending on the voltage type, the method includes selecting a power mode among a plurality of power modes that include fault managed power modes at different voltages and at least one non-fault managed power mode. The method then includes entering a selected power mode.

In another form, a method is provided that is performed by a power transmitter to provide power to a power receiver. The method includes, upon powering up of the power transmitter, determining a type of an input voltage to the power transmitter. Depending at least on a type of the input voltage and an operational state of the power transmitter, the method includes selecting one of a plurality of power modes that include fault managed power modes at different voltages, at least one non-fault managed power mode and an alternating current (AC) power mode. The method further includes transmitting power according to a selected power mode.

### Example Embodiments

The embodiments presented herein relate to several power modes for FMP Power Source Equipment (PSE), Powered Devices (PDs) and other front-end powering systems. Before deployment of FMP related techniques, there were several basic power system arrangements that are described briefly below.

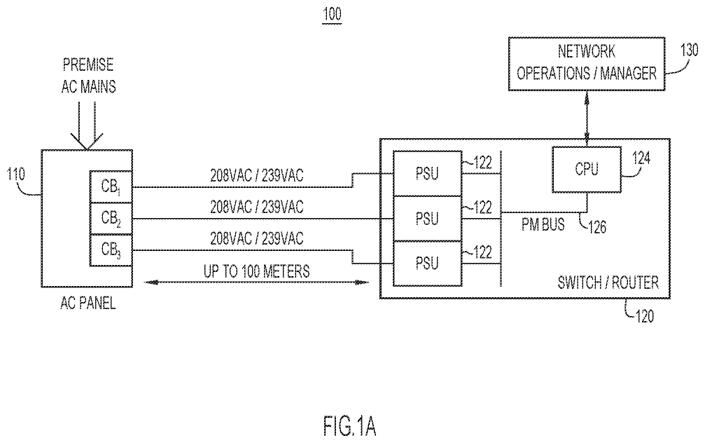

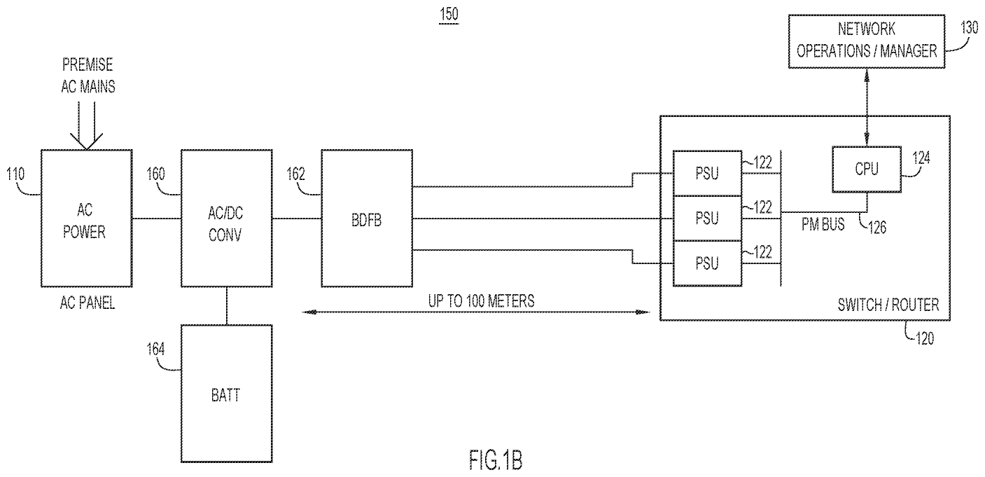

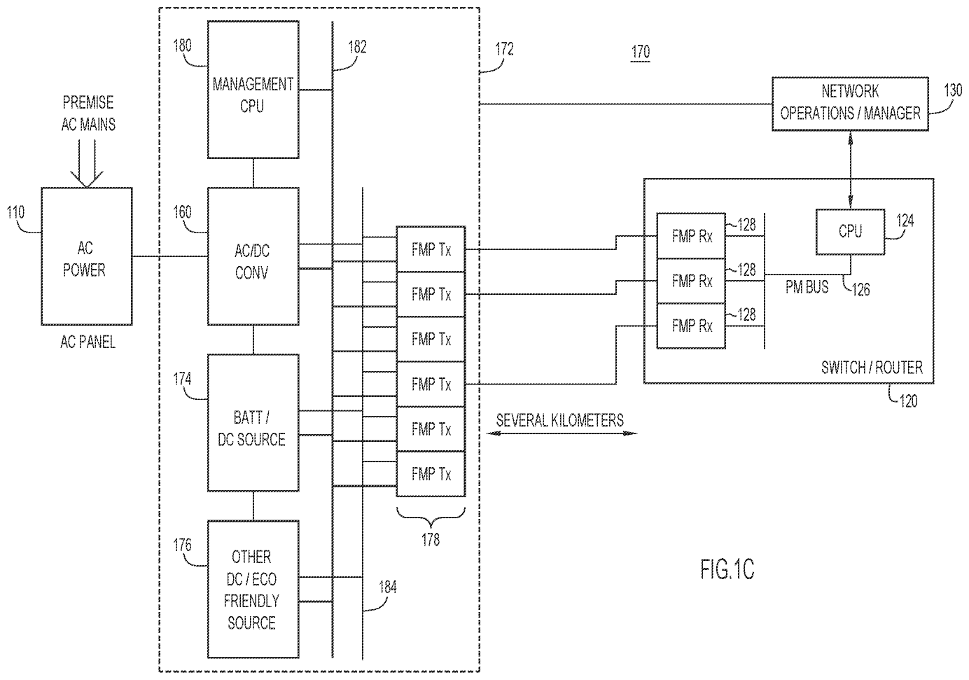

FIG. 1A illustrates a diagram of a conventional AC power system 100. The system 100 includes an AC panel 110 that is connected to premise AC mains power. The AC panel 110 provides power to a networking/computing device 120. The networking/computing device 120 may be a networking switch, router or other equipment, and is simply referred to as device 120. The device 120 includes a plurality of power supply units (PSUs) 122 and a central processing unit (CPU) 124. The CPU 124 communicates with the PSU via a power management (PM) bus 126 but this could be any communications bus. The CPU 124 is in communication with a network operations/manager platform 130. The AC panel 110 may be a 3-phase panel providing, for example, 208 Volts AC (VAC) or 239 VAC, to respective ones of the PSUs 122 in the device 120. In the system 100, the CPU 124 reads from the PSUs 122 for information about available functions that are defined. The distance between the AC panel 110 and the device 120 is typically up to 100 meters.

FIG. 1B illustrates a conventional DC-based power system 150. The system 150 includes an AC panel 110 that receives premise AC mains power, an AC/DC converter 160, a battery distribution fuse bay (BDFB) 162, a battery 164 and a device 120 (similar to the device 120 shown in FIG. 1A). The BDFB 162 may provide 48 VDC, 240 VDC and/or 380 VDC, to the device 120. The system 150 thus may provide 48 VDC, 240 VDC or 380 VDC. Like the system 100 shown in FIG. 1A, the distance between the AD/DC converter 160 may typically be up to 100 meters.

FIG. 1C illustrates an FMP power system 170 that includes an AC panel 110, a FMP power sourcing device 172 that includes AC/DC converter 160, a battery or DC source 174, one or more other DC/eco-friendly sources 176, a plurality of FMP transmitters (TX) 178 and an optional management CPU 180. The FMP power sourcing device 172 may include a management bus 182 to which the management CPU 180 is connected and uses to communicate with the other components of the FMP power sourcing device 172. The AC/DC converter 160, battery/DC source 174 and the one or more other DC/eco-friendly sources 176 are coupled to the FMP transmitters 178 via power bus 184.

The device 120 includes a plurality of FMP receivers (RX) 128 that receive power from the FMP transmitters 178. In the system 170, the distance between the FMP power sourcing device 172 and the device 120 may be several kilometers.

In the power systems shown in FIGS. 1A and 1B, the following are the most approved PSU combinations:
PSU 48 VDC—Covers 40 VDC to 72 VDC and is typically a unique and separate product identifier (PID).
PSU AC/HVDC—Covers AC and High Voltage (HVDC). One PSU PID covers all these voltages: 208 VAC, 239 VAC, 277 VAC, 240 VDC, and 380 VDC

With FMP, the following combinations would be useful:
PSU 48 VDC and FMP—Covers 48 VDC and FMP
PSU AC/HVDC/FMP—Covers AC, HVDC and FMP: 208 VAC, 239 VAC, 277 VAC, 240 VDC, 380 VDC and FMP

Presented are systems and methods for a universal FMP (front end or PSU) power system that can accommodate negotiation to support any of the aforementioned voltage power scenarios and other voltage power scenarios hereinafter developed. FMP class 4 power is assumed to be 380 VDC, but it may be some other voltage power scenario.

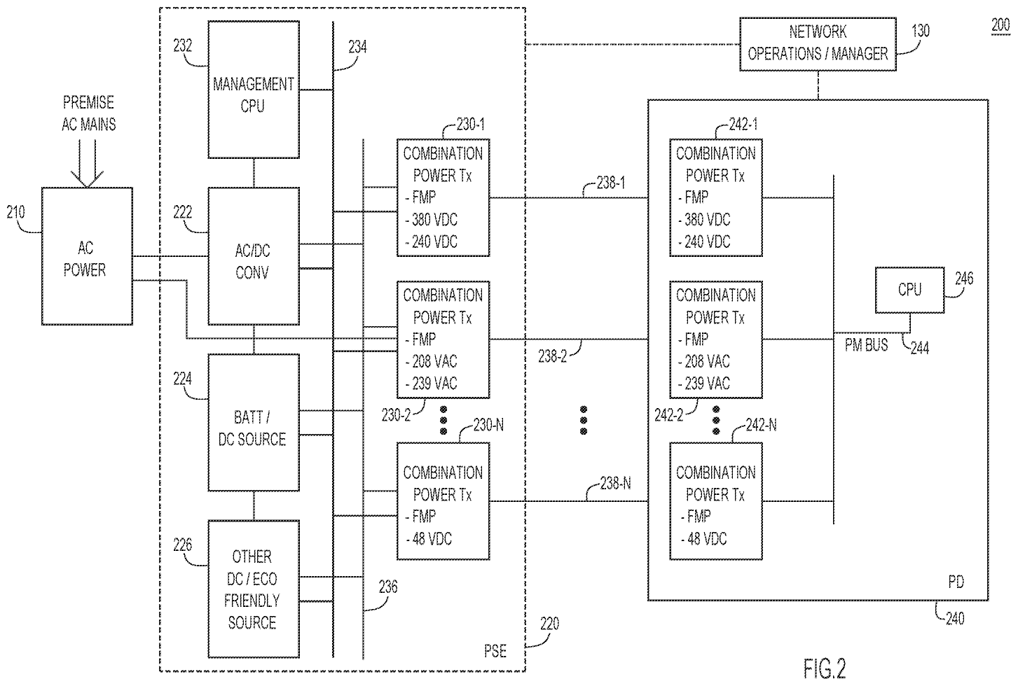

Reference is now made to FIG. 2 that shows a power system 200 according to one embodiment that can support automatic power configuration sensing involving a power sourcing equipment and a powered device. The system 200 includes an AC power panel 210, a power sourcing equipment (PSE) 220 and a powered device (PD) 240. The PSE 220 includes an AC/DC converter 222, a battery/DC source 224, one or more other eco-friendly DC sources 226, a plurality of combination power transmitters 230-1, 230-2, . . . , 230-N and optional management CPU 232. Communication between the management CPU 232 and the various other components may be via the management bus 234. Power is provided from the AC/DC converter 222, battery/DC source 224 and one or more other eco-friendly DC sources 226 to the combination power transmitters 230-1-230-N by way of a power bus 236.

The combination power transmitters 230-1-230-N have the ability to transmit multiple power types (other than just FMP class 4 power). This allows a “combination” PSU source to be created to server multiple needs. For example, and not by way of limitation, as shown in FIG. 2, combination power transmitter 230-1 has the ability to transmit FMP power, 380 VDC and 240 VDC; combination power transmitter 230-2 has the ability to transmit FMP power, 208 VAC, and 239 VAC; and combination power transmitter 230-N has the ability to transmit FMP power and 48 VDC. A plurality of cables 238-1, 238-2, . . . 238-N connect the combination power transmitters to the PD 240. The plurality of cables 238-1-238-N could be combined into a single cable bundle.

The PD 240 includes a plurality of combination power receivers 242-1, 242-2, . . . , 242-N, a power management bus 244 and a CPU 246. The PD 240, via operations of the CPU 246, negotiates with the PSE 220, via operations of the management CPU 232, among multiple power types, according to the needs of the PD 240. This allows “one” PSU module to be deployed at the PD 240, and to negotiate the power type that the PSE 220 can provide to the PD 240 as part of an auto-negotiation method described below, to determine the best and safest/efficient power method(s) to be used for a given PD.

Management communications between the network operations/manager platform 130 and the management CPU 232 of the PSE 220 and the CPU 246 of the PD 240 is optional, and is not required in connection with the techniques presented herein.

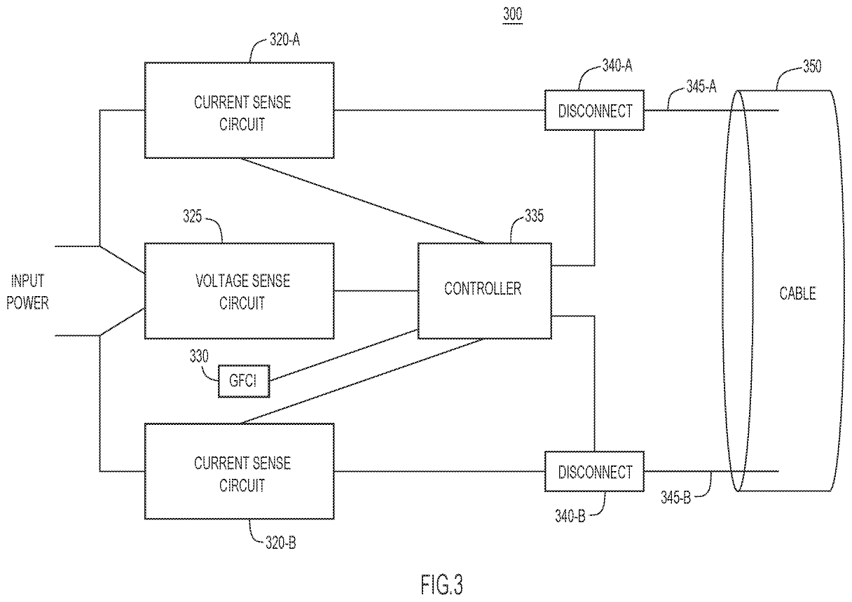

Reference is now made to FIG. 3, which shows a block diagram of a power transmitter 300 (i.e., Power Source Equipment (PSE)) configured to perform and participate in the techniques presented herein. The power transmitter 300 may include two current sense circuits (current sensors) 320-A and 320-B, a voltage sense circuit (voltage sensor) 325, a ground fault circuit interrupter (GFCI) 330, a controller 335 and two disconnects 340-A and 340-B. The GFCI 330 can operate any time (even when power is being delivered onto lines 345-A and 345-B) because it looks for mismatches as to what current is sent on one line and what current comes back on the other line.

The current sense circuits 320-A and 320-B are associated with respective lines of a loop, and are coupled to the disconnects 340-A and 340-B, respectively, which are in turn connected to lines 345-A and 345-B that may be contained within a cable 350.

Power is input onto two current paths. Each of these current paths traverses a current sensor, e.g., current sense circuit 320-A and 320-B, and their relative voltage is measured by the voltage sense circuit 325. The controller 335 receives the measurements from the current sense circuits 320-A and 320-B and the voltage sense circuit 325. The controller 335 may also be responsive to the GFCI 330 during power delivery time periods for added safety. The current sense circuits 320-A and 320-B measure current and passes these values to the controller 335. The current then flows to disconnect 340-A onto line 345-A into the cable 350 (to the power receiver) and comes back on the return current path on line 345-B into disconnect 340-B.

The controller 335 actuates at least one of the disconnects 340-A and 340-B to isolate power source current from the lines 345-A and 345-B (forming a current loop when connected at opposite ends to a power receiver) in the event safety criteria is not met according to the evaluation by the controller 335 of the line conditions (line-to-line fault detection, a line-to-ground fault as detected by the GFCI 330, or other current or voltage conditions detected by the controller 335). The disconnects 340-A and 340-B may be relays or switches, such as field effect transistor (FET) switches, and in some embodiments, back-to-back FETs. The controller 335 may be a microprocessor, microcontroller or other digital logic device (with fixed or programmable digital logic gates) configured to perform the techniques described herein. To the right of the disconnects 410-A and 410-B are lines that connect to a load, and there may be, between the disconnects 410-A and 410-B and the load, a DC-DC converter or AC-DC converter.

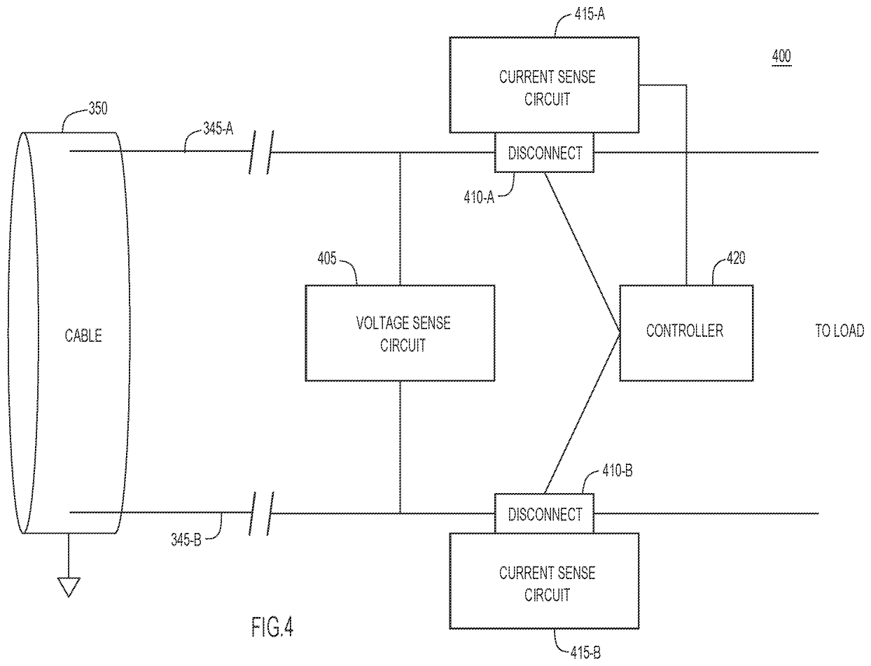

FIG. 4 is a block diagram of a power receiver (i.e., Powered Device (PD)) 400 that is coupled to a cable, e.g., cable 350 containing lines 345-A and 345-B from the power transmitter shown in FIG. 3, as an example.

The power receiver 400 includes a voltage sense circuit 405, disconnects 410-A and 410-B that are connected to lines 345-A and 345-B, respectively, current sense circuits 415-A and 415-B connected to sense current on lines 345-A and 345-B, respectively, and a controller 420. As explained above, the lines 345-A and 345-B form a current loop between a power transmitter and the power receiver 400.

The power receiver 400 receives power on lines 345-A and 345-B of the cable 350 as input, with an optional ground reference. The voltage sense circuit 405 makes a voltage measurement on the incoming power for telemetry, loop resistance calculation, or any other reason associated with the techniques presented herein. This current path then traverses disconnects 410-A and 410-B as well as current sense circuits 415-A and 415-B on the respective line to enforce current limits. The disconnects 410-A and 410-B may be FETs, relays, etc.

The controller 420 may be a microprocessor, microcontroller or other digital logic device (with fixed or programmable digital logic gates) configured to perform the fault detection and alerting techniques described herein. The controller 420 may be configured to modulate at least one of the disconnects 410-A and 410-B by disconnecting the further power reception stages at the required interval to force a known current draw (likely near zero, but not necessarily). This demonstrates to the power transmitter that no faults are present on the lines 345-A and 345-B and the power receiver is up and running. An optional load equipment ground conductor may be provided if grounding of the load is required/desirable.

Again, one task of the controller 420 is to drive the at least one of disconnects 410-A and 410-B to disconnect from at least one of the lines 345-A and 345-B, respectively, to demonstrate safety at the required interval. The current sense circuits 415-A and 415-B may be employed to provide telemetry, and also to provide current measurement to the controller 420 if the load pulls too much current, serving as a backup plan if there is a short-circuit, etc.

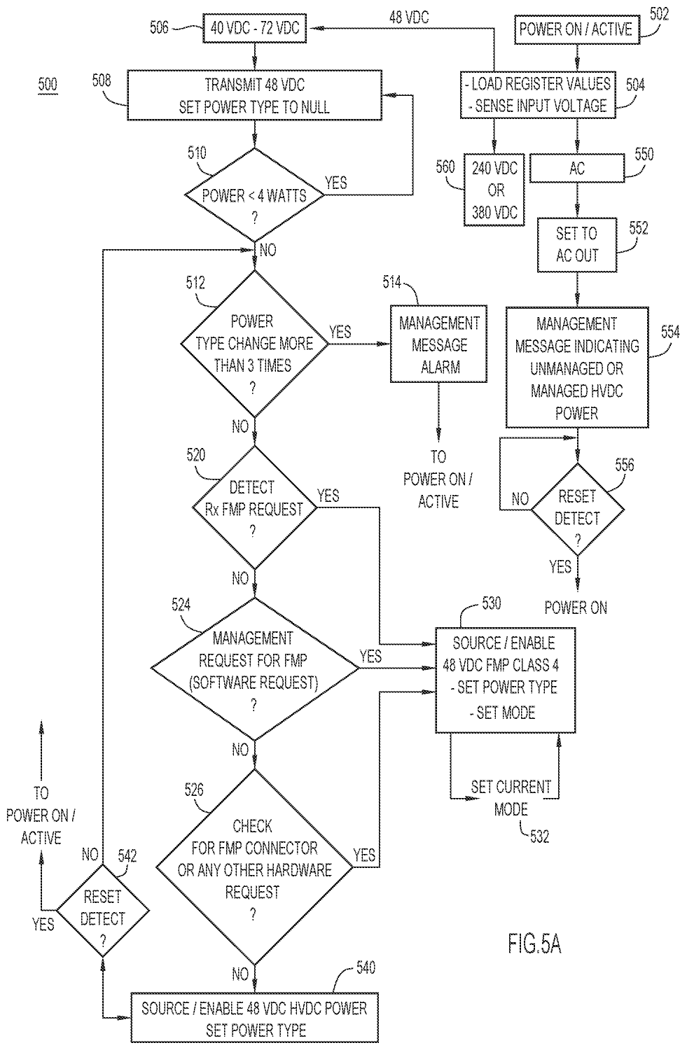

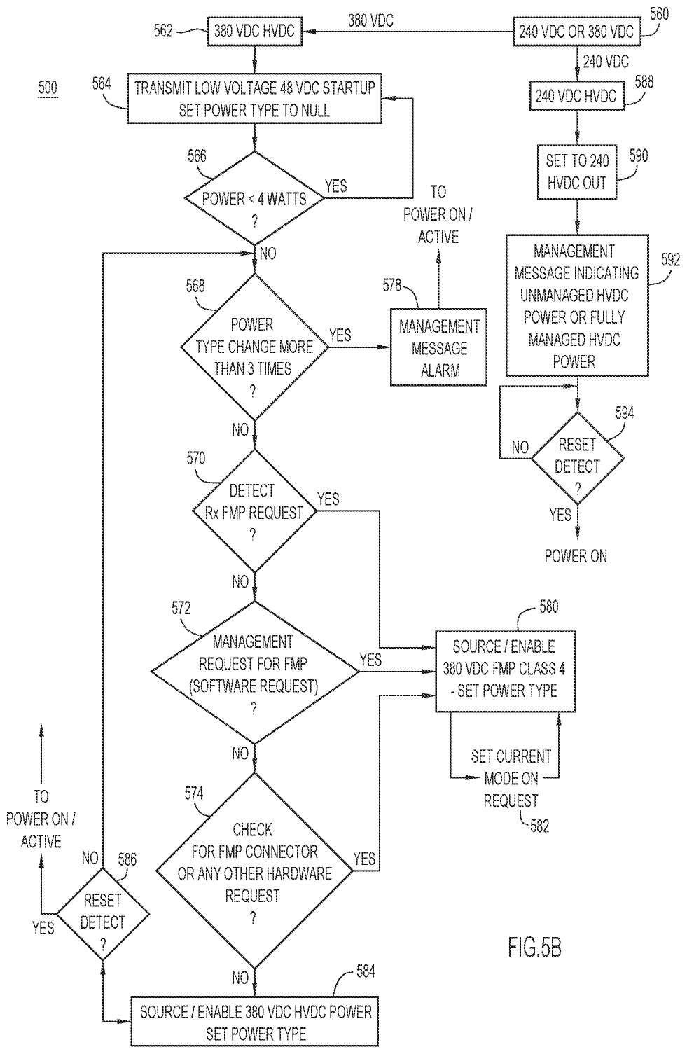

Turning now to FIGS. 5A and 5B, a state diagram/flowchart 500 depicting operations of respective combination power transmitters 230-1, 230-2, . . . , 230-N is now described. The operation of the individual combination power transmitters 230-1, 230-2, . . . , 230-N (referred to simply as a “power transmitter” or “power Tx/TX”), depends on what type of power is received at their respective inputs, as now described. Reference is also made to FIGS. 2 and 3 in connection with the description of the state diagram 500 shown in FIGS. 5A and 5B. To this end, the management CPU 232 in the PSE 220 may control which type of power is provided to respective ones of the power transmitters 230-1 to 230-N, which in turn triggers the specific path a power transmitter takes through the state diagram 500 for operation, as described below.

At 502, the power transmitter enters a power-on/active state when the power transmitter turns on. At 504, the controller of the power transmitter loads registers values for operation, and the power transmitter senses the voltage it receives at its input, e.g., from the AC/DC converter 222, the AC power panel 210, the battery/DC source 224 or other DC/eco-friendly source 226.

Based on the input voltage sensed at 504, one of various paths can be taken through FIGS. 5A and 5B. If the input voltage sensed by the power transmitter is 48 VDC, then the path to the left of FIG. 5A is taken as shown at 506 (40 VDC-72 VDC), and is now described. Next, at 508, the power transmitter transmits 48 VDC on the associated cable to the PD. The controller of the power transmitter stores an indication of the power type being “null” at this stage.

Next, at 510, the controller of the power transmitter determines whether the transmit power is less than a predetermined power level, e.g., 4 watts, and if so, the controller returns to state 508 to again transmit 48 VDC. If the power is more than the predetermined power level, then at 512, the controller of the power transmitter determines whether the power type has changed more than a predetermined number of times, e.g., 3 times. If the power type has changed more than the predetermined number of times, then this could an indication of an issue and at 514, a management message alarm is triggered to the management CPU 232 of the PSE 220. After that, the process returns to the power-on/active state 502.

If the power type has not changed more the predetermined number of times, then the process continues to 520 at which a check is made for activity from the power receiver side. At 520, a detection is made for an FMP request from the power receiver side. If no FMP request is detected from the power receiver side, then the process continues as described below. However, if an FMP request 520 is received from the power receiver side, then source/enable state 530 is entered where the power type is set to 48 VDC FMP Class 4 power. Also, in state 530, the mode is set. For example, as shown at 532, if the power receiver requests current mode, then that mode is set in state 532.

If at 520 there is no FMP request from the power receiver, then at 524, a check is made whether a management request (a software request) for FMP has been received, and if so, the process goes to state 530. If a management request for FMP is not received, then at 526 a check is made for connection of an FMP connector or for any other hardware request. If an FMP connector or other hardware request is received, then the process goes to state 530; otherwise, the process goes to state 540.

In state 540, the 48 VDC telecommunication (telco) power type is set. At 542, a reset detect state is entered, and if a reset is detected, then the process reverts to the power-on/active state 502. Otherwise, the process goes to step 512 to detect a power type change.

If, at 504, AC voltage is detected, then the AC state 550 is entered. Next, at 552, the power transmitter sets the power type to AC out. At 554, a management message is generated indicating that the power is unmanaged AC power or is fully managed AC power.

Next, at 556, a reset detect state is entered. If a reset is detected, then the process reverts to the power-on/active state 502. Otherwise, the process stays in state 556.

Referring back to step 504, if the sensed input voltage is 240 VDC or 380 VDC, then step 560 is entered. Reference is now made to FIG. 5B. In step 560, if it is determined that the power is 380 VDC (corresponding to a type of High Voltage DC (HVDC) power), then state 562 is entered. At 564, a low voltage startup of 48 VDC is transmitted and the power type is set to “null”. Thereafter, at 566, it is determined whether the power is less than 4 watts, and if so, the process reverts to step 564, and otherwise, at 568, it is determined whether the power type has changed more than 3 times, and if so, the process goes to step 578 where a management message alarm is generated and the process reverts to the power-on/active state 502. At step 570, it is determined whether an FMP request is received from the power receiver, and if not, at step 572 it is determined whether a management request for FMP is received. If a management request for FMP is not received, a check is made at step 574 for an FMP connector or any other hardware request. If any of steps 570, 572 and 574 are affirmative, then the process goes to state 580 for source/enable of 380 VDC FMP Class 4 power (and the mode may be set to current mode upon request from the power receiver at 582). If all the steps 570, 572 and 574 are in the negative, then the process goes to state 584 for source/enable of 380 VDC HVDC power, followed by reset detect at 586.

If at 560, it is determined that the input voltage is 240 VDC, then state 588 is entered. Next, at 590, the power transmitter is set to 240 HVDC out. Thereafter, at 592 a management message is generated indicating unmanaged HVDC power of fully managed HVDC power, and the process then goes to a reset state 594. It should be noted that if FMP was to allow a 240 VDC voltage in the Class 4 fault managed power description, then the operations of FIG. 5B would be duplicated to allow for a configuration of 240 VDC FMP, similar to 380 VDC and 48 VDC configurations. This would be similar for both transmitter and receiver operations.

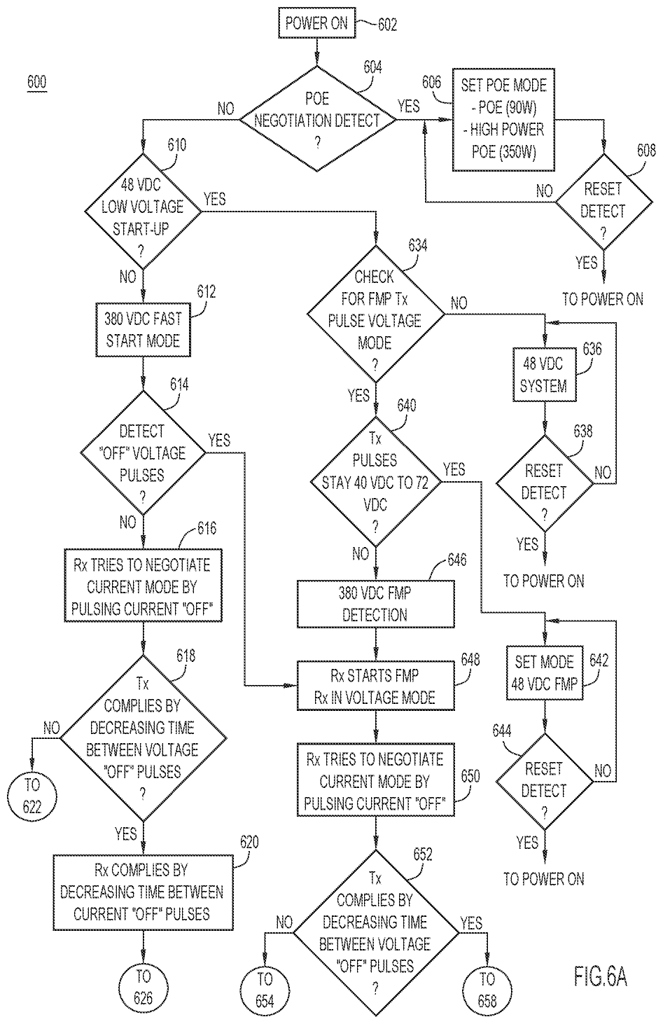

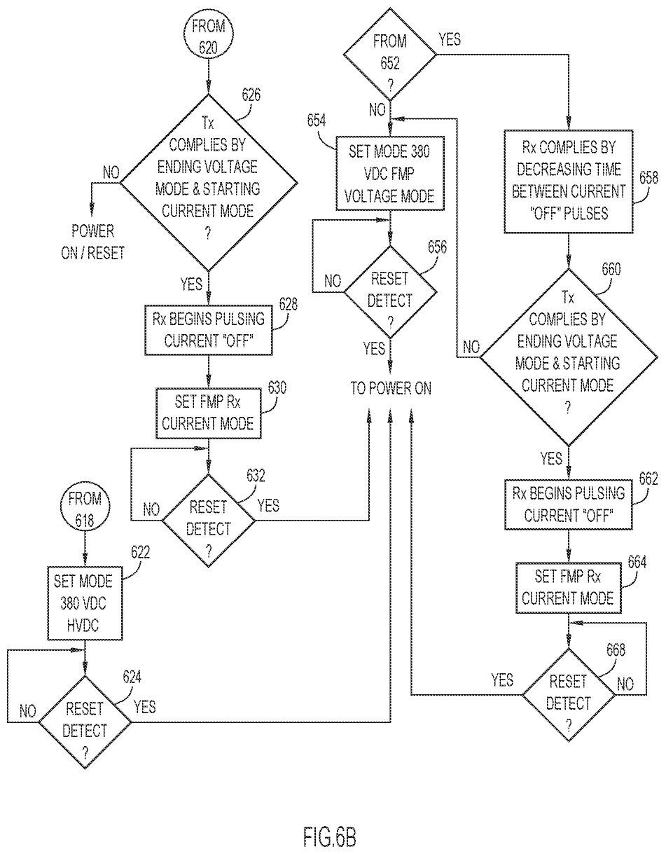

FIGS. 6A and 6B illustrate a flow chart 600 depicting the operations of a power receiver. Reference is also made to FIGS. 2 and 4 for purposes of the description of FIGS. 6A and 6B. A power receiver powers on at state 602, and it next performs, at 604, a Power-over-Ethernet (PoE) negotiation detection operation to detect a voltage pattern indicative of a PoE connection available on the cable. If a PoE negotiation detection occurs, then at 606, the power receiver sets its mode to PoE mode, the power type to 90 watts or high power PoE (350 watts). At 608, the power receiver enters a reset detect state. If a reset is not detected, the process reverts to 606, but if a reset is detected, then the process reverts to power-on state 602.

When, at 604, PoE negotiation detection does not occur, then the process goes to state 610 to attempt 48 VDC low voltage start-up. When low voltage start-up does not occur, then the process goes to state 612 for a 380 VDC fast start mode. Next, at 614, detection is made for voltage pulses from the power transmitter. If voltage pulses are not detected, then at 616, the power receiver tries to negotiate a current mode with the power transmitter by pulsing current “off” on the cable. At 618, the power receiver determines whether the power transmitter complies with the current “off” pulsing by decreasing time between voltage “off” pulses of the voltage pulses, and if so, at 620 the power receiver complies by decreasing time between current “off” pulses. If the power receiver, at 618, determines that the power transmitter does not decrease time between voltage “off” pulses, then the process continues to 622 (in FIG. 6B) in which the power receiver sets the mode to 380 VDC HVDC. Thereafter, the power receiver enters the reset detect state 624 and stays there unless a reset is detected, at which point it returns to the power-on state 602.

Referring back to FIG. 6A, when the power receiver, at 614, detects “off” voltage pulses, then the process goes to a branch that is described further below. After 620 when the power receiver decreases time between current “off” pulses, then in FIG. 6B, the process continues at 626 where the power receiver determines whether the power transmitter complies by ending voltage mode and starting current mode. If not, the power receiver reverts to the power-on state 602. If the power receiver determines that the power transmitter has ended voltage mode and starts current mode operation, then at 628, the power receiving begins pulses current “off”, then at 630, sets its mode to FMP receiver current mode. The power receiver then goes to reset detect state 632 until and if a reset is detected, at which point it reverts to the power-on state 602.

When, at 610, the processor detects a 48 VDC low voltage start-up, then at 634, the processor checks for whether the transmitter is in pulse voltage mode. If the power receiver does not detect that the power transmitter is in pulse voltage mode, then at 636, the power receiver sets the 48 VDC mode and thereafter enters the reset detect state 638. The power receiver stays in the reset detect state until and if a reset is detected, at which point it reverts to the power-on state 602. If the power receiver, at 634, detects that the transmitter is in pulse voltage mode, then the process goes to 640 to detect transmit pulses that stay within a predetermined range, e.g., between 40 VDC and 72 VDC. When the power receiver detects that the pulses are between 48 VDC to 72 VDC, then at 642, the power receiver sets its mode to 48 VDC FMP. Then, the power receiver goes into the reset detect state 644 and stays there until and if a reset is detected, at which point the power receiver reverts to the power-on state 602.

When at 640, the power receiver determines that the transmit pulses are not between 40 VDC and 72 VDC, then at 646, the power receiver enters 380 VDC FMP detection state. Next, at 648, the power receiver starts FMP receiver operation in voltage mode. Operation 648 is also entered when, in 614, “off” voltage pulses are detected. Next, at 650, the power receiver tries to negotiate current mode by pulsing current “off”. At 652, the power receiver determines whether the power transmitter complies by decreasing time between voltage “off” pulses. When the power receiver determines that the power transmitter does not decrease time between voltage “off” pulses, then at 656, the power receiver sets its mode to 380 VDC FMP voltage mode, and then enters the reset detect state 656 until a reset is detected.

When the power receiver determines that the power transmitter does decrease time between voltage “off” pulses, then at 658, the power receiver complies by decreasing time between current “off” pulses. Next, at 660, the power receiver determines whether the power transmitter complies by ending voltage mode and starting current mode. When the power receiver determines that the power transmitter does not comply, the process goes to state 654 where the power receiver sets its mode to 380 VDC FMP voltage mode. When the power receiver determines that the power transmitter ends voltage mode and starts current mode, then at 662, the power receiver begins pulsing current “off” and at 664, and sets its mode to FMP receiver current mode. Then the power receiver enters reset detect state 668 until a reset is detected.

It should be understood that FMP can operate at 240 VDC. Therefore, the receiver operation diagrams of FIGS. 6A and 6B can be adapted to apply for FMP 240 VDC (for the same reason it applies to FMP 380 VDC and FMP 48 VDC). To avoid any further complexity in the diagrams of FIGS. 6A and 6B, FMP 240 VDC was left out.

Furthermore, in the FMP fast start operations (state 612 and below as well operations 646 and below in FIGS. 6A and 6B), if the power transmitter complies with negotation for current mode, and then does not follow up with an acknowledgment, the power receiver should go to an “error” state or reset/power-on state. Sending the power receiver to voltage mode at this point may be unsafe.

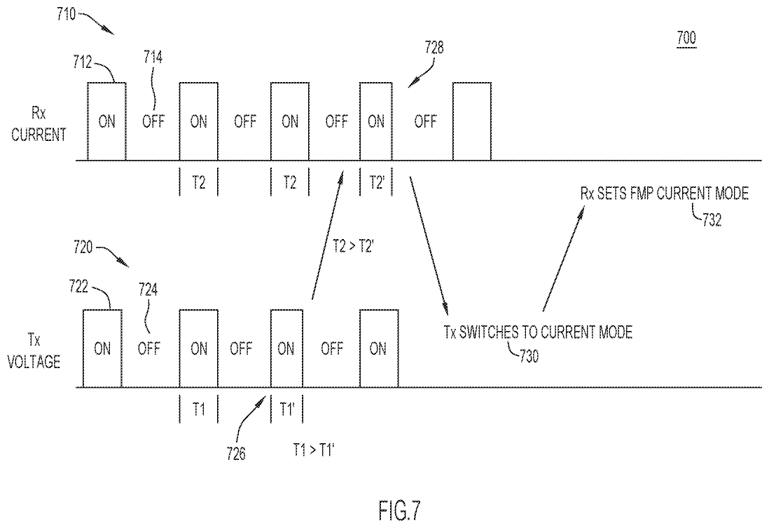

As described above in connection with FIGS. 6A and 6B, the power receiver may initiate a scheme of pulsing current to the power transmitter as means to signal to the power transmitter that the power receiver is attempting to negotiate FMP current mode, and the power transmitter may or may not comply with the power receiver's request for current by a pulsing scheme. FIG. 7 depicts, in more detail, this pulsing signaling scheme 700 between a power transmitter and a power receiver, and in particular corresponds to the operations depicted by steps 616, 618, 620, 622, 626, 628 and 630 as well as steps 650, 652, 654, 658, 660, 662 and 664 in FIGS. 6A and 6B.

FIG. 7 shows, at reference numeral 710, a current pulse waveform that a power receiver (Rx) sends to a power transmitter (Tx), and at reference numeral 720, a voltage pulse waveform that a power transmitter (Tx) sends to the power receiver. The current pulse waveform 710 has “on” pulses 712 and “off” pulses 714. Similarly, the voltage pulse waveform 720 has “on” pulses 722 and “off”' pulses 724.

When a power receiver tries to negotiate current mode with the power transmitter, the power receiver pulses a current waveform like the waveform shown at 710 to the power transmitter via conductors in the cable between the power transmitter and power receiver. The power transmitter will detect the current pulse waveform and start decreasing the time T1 between consecutive “off” pulses 724 in the voltage pulse waveform 720. Thus, as shown at 726, the time between “off” pulses in the voltage pulse waveform 720 is decreased to T1′. The power receiver detects the voltage pulse waveform 720 received from the power transmitter and detects that the time period between “off” pulses of the voltage pulse waveform 720 has decreased. In reply, the power receiver decreases the time T2 between consecutive “off” pulses in the current pulse waveform 710. As shown at 728, the time between “off” pulses of the current pulse waveform 710 is decreased to T2′. The power transmitter detects the decrease in time between “off”' pulses of the current pulse waveform, and in response, at 730, switches to current mode, and starts deliver FMP pulsed current power to the power receiver. (This change in the power waveform generated by the power transmitter is not shown in FIG. 7, for simplicity.) The power receiver, in response, to seeing the power transmitter switch to current mode, sets it power mode to FMP current mode, as shown at 732.

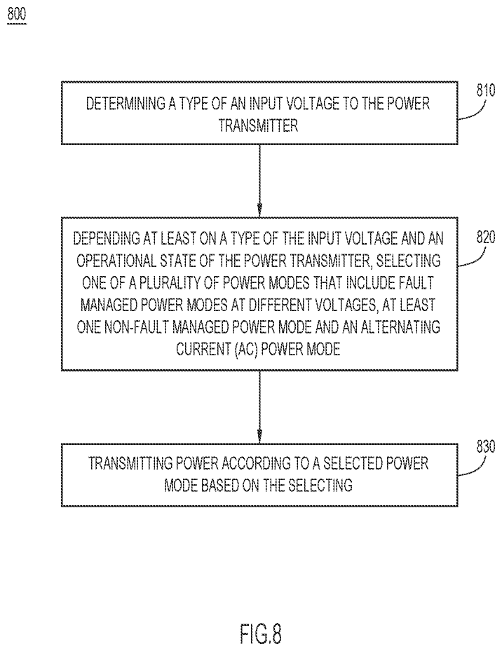

Reference is now made to FIG. 8, which shows a flow chart depicting a method 800 performed by a power transmitter, according to the techniques presented herein, provide power to a power receiver. The method 800, includes, at step 810, upon powering up of the power transmitter, determining a type of an input voltage to the power transmitter. At step 820, the method 800 includes, depending at least on a type of the input voltage and an operational state of the power receiver, selecting one of a plurality of power modes that include fault managed power modes at different voltages, at least one non-fault managed power mode and an alternating current (AC) power mode. At step 830, the method 800 includes transmitting power according to a selected power mode based on the selecting step 820.

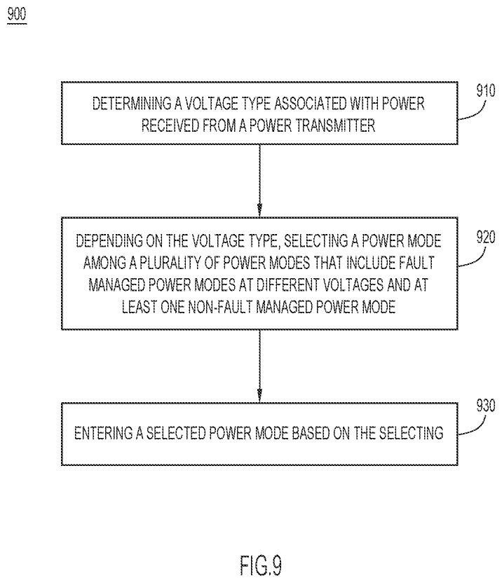

Turning to FIG. 9, a flow chart is shown that depicts a method 900 performed by a power receiver, according to the techniques presented herein. At step 910, the method 900 includes, upon powering up or upon power reset, determining a voltage type associated with power received from a power transmitter. At step 920, the method 900 includes, depending on the voltage type, selecting a power mode among a plurality of power modes that include fault managed power modes at different voltages and at least one non-fault managed power mode. At step 930, the method 900 includes entering a selected power mode based on the selecting step 920.

In some aspects, the techniques described herein relate to a method performed by a power receiver, including: upon powering up or upon power reset, determining a voltage type associated with power received at the power receiver from a power transmitter; depending on the voltage type, selecting a power mode among a plurality of power modes that include fault managed power modes at different voltages and at least one non-fault managed power mode; and entering a selected power mode based on the selecting.

In some aspects, the techniques described herein relate to a method, wherein determining includes determining whether the voltage type is a direct current (DC) voltage at a first voltage level, and further including: when the voltage type is the DC voltage at the first voltage level, determining whether the power received is indicative of a pulse voltage mode fault managed power.

In some aspects, the techniques described herein relate to a method, wherein when the power received is not indicative of pulse voltage mode fault managed power, selecting includes selecting a non-fault managed power mode at the first voltage level.

In some aspects, the techniques described herein relate to a method, wherein when the power received is indicative of pulse voltage mode fault managed power, further including: determining whether DC pulses of the power are within a predetermined voltage range, wherein selecting includes selecting a fault managed power mode at the first voltage level when the DC pulses of the power are within the predetermined voltage range.

In some aspects, the techniques described herein relate to a method, wherein when the DC pulses of the power are not within the predetermined voltage range, further including: sending current pulses from the power receiver to the power transmitter in an attempt to negotiate a current mode power; and determining whether the power transmitter responds to the current pulses by decreasing time between voltage “off” periods of the DC pulses, wherein selecting includes selecting as the selected power mode, fault managed power at a second voltage level greater than the first voltage level when the power transmitter does not decrease time between voltage “off” periods of the DC pulses in response to sending the current pulses.

In some aspects, the techniques described herein relate to a method, wherein when it is determined that the power transmitter responds to the current pulses by decreasing time between voltage “off” periods of the DC pulses, further including: decreasing time between “off” periods of the current pulses sent from the power receiver to the power transmitter; determining whether the power transmitter stops sending DC voltage pulses and starts sending DC current pulses; when it is determined that the power transmitter stops sending DC voltage pulses and starts sending DC current pulses, selecting includes selecting as the selected power mode a fault managed power current mode; and when it is determined that the power transmitter does not stop sending DC voltage pulses and start sending DC current pulses, selecting includes selecting as the selected power mode, fault managed power at the second voltage level.

In some aspects, the techniques described herein relate to a method, wherein when the voltage type is not a DC voltage at a first voltage level, further including: determining whether the power received from the power transmitter includes voltage pulses with “off” time periods; when the power includes voltage pulses with “off” time periods, sending current pulses from the power receiver to the power transmitter in an attempt to negotiate current mode power; determining whether the power transmitter responds to the current pulses by decreasing time between voltage “off” periods of the voltage pulses; and when the power transmitter does not decrease time between voltage “off” periods of the voltage pulses, selecting includes selecting a high voltage DC power mode at a second voltage level greater than the first voltage level.

In some aspects, the techniques described herein relate to a method, wherein when it is determined that the power transmitter responds to the current pulses by decreasing time between voltage “off” periods of the voltage pulses, further including: decreasing time between “off” periods of the current pulses sent from the power receiver to the power transmitter; determining whether the power transmitter stops sending voltage pulses and starts sending current pulses; and when it is determined that the power transmitter stops sending voltage pulses and starts sending current pulses, selecting includes selecting as the selected power mode a fault managed power current mode.

In some aspects, the techniques described herein relate to a method, wherein when it is determined that the power transmitter does not stop sending voltage pulses and start sending current pulses, further including performing a power reset of the power receiver.

In some aspects, the techniques described herein relate to a method performed by a power transmitter to provide power to a power receiver, including: upon powering up of the power transmitter, determining a type of an input voltage to the power transmitter; depending at least on a type of the input voltage and an operational state of the power transmitter, selecting one of a plurality of power modes that include fault managed power modes at different voltages, at least one non-fault managed power mode and an alternating current (AC) power mode; and transmitting power according to a selected power mode based on the selecting.

In some aspects, the techniques described herein relate to a method, when the input voltage is a direct current (DC) voltage at a first voltage level: initially transmitting DC voltage at the first voltage level; and selecting includes as the selected power mode a fault managed power at the first voltage level when the operational state of the power receiver indicates that the power receiver requests fault managed power, and otherwise selecting includes selecting non-fault managed power.

In some aspects, the techniques described herein relate to a method, wherein selecting includes selecting fault managed power at the first voltage level based on any one of: detecting a request from the power receiver for fault managed power; receiving from a management controller associated with the power transmitter a management request for use of fault managed power; or detecting a fault managed power connector associated with the power receiver.

In some aspects, the techniques described herein relate to a method, when the input voltage is a DC voltage at a second voltage level: initially transmitting DC voltage at a first voltage level less than the second voltage level; and selecting includes as the selected power mode a fault managed power at the second voltage level when the operational state of the power receiver indicates that the power receiver requests fault managed power, and otherwise selecting includes selecting DC power at the second voltage level.

In some aspects, the techniques described herein relate to a method, wherein selecting includes selecting fault managed power at the second voltage level based on any one of: detecting a request from the power receiver for fault managed power; receiving from a management controller associated with the power transmitter a management request for use of fault managed power; or detecting a fault managed power connector associated with the power receiver.

In some aspects, the techniques described herein relate to a method, when the input voltage is a DC voltage at a third voltage level, selecting includes selecting DC power at the third voltage level, and further including: generating a management message indicating unmanaged power or fully managed power at the third voltage level.

In some aspects, the techniques described herein relate to a method, when the input voltage is an AC voltage, selecting includes selecting AC power, and further including: generating a management message indicating unmanaged AC power or fully managed AC power.

In some aspects, the techniques described herein relate to a power receiver including: a voltage sense circuit configured to determine a voltage type associated with power received on a cable from a power transmitter; and a controller coupled to the voltage sense circuit, wherein the controller is configured to select a power mode among a plurality of power modes that include fault managed power modes at different voltages and at least one non-fault managed power mode, and to cause the power receiver to enter a selected power mode.

In some aspects, the techniques described herein relate to a power receiver, wherein the controller is further configured to determine whether the power is indicative of a pulse voltage mode fault managed power when the voltage type is a direct current (DC) voltage at a first voltage level.

In some aspects, the techniques described herein relate to a power receiver, wherein the controller is configured to select a non-fault managed power mode at the first voltage level when the power received is not indicative of pulse voltage mode fault managed power.

In some aspects, the techniques described herein relate to a power receiver, wherein when the power received is indicative of pulse voltage mode fault managed power the controller is configured to: determine whether DC pulses of the power are within a predetermined voltage range; and select a fault managed power mode at the first voltage level when the DC pulses of the power are within the predetermined voltage range.

In some aspects, the techniques described herein relate to a power transmitter including: a voltage sense circuit configured to sense an input voltage of input power to the power transmitter; and a controller coupled to the voltage sense circuit, wherein the controller is configured to, depending at least on a type of the input voltage and an operational state of the power transmitter, select one of a plurality of power modes to transmit power to a power receiver, the plurality of power modes including fault managed power modes at different voltages, at least one non-fault managed power mode and an alternating current (AC) power mode, depending at least on a type of the input voltage and an operational state of the power transmitter.

In some aspects, the techniques described herein relate to a power transmitter, wherein, when the input voltage is a direct current (DC) voltage at a first voltage level, the controller is configured to: cause a DC voltage to initially be transmitted at the first voltage level; and select as the selected power mode a fault managed power at the first voltage level when the operational state of the power receiver indicates that the power receiver requests fault managed power, and otherwise select non-fault managed power.

In some aspects, the techniques described herein relate to a power transmitter, wherein the controller is configured to select fault managed power at the first voltage level based on any one of: detecting a request from the power receiver for fault managed power; receiving from a management controller associated with the power transmitter a management request for use of fault managed power; or detecting a fault managed power connector associated with the power receiver.

In some aspects, the techniques described herein relate to a power transmitter, wherein when the input voltage is a DC voltage at a second voltage level, the controller is configured to: cause DC voltage to be transmitted at a first voltage level less than the second voltage level; and select as the selected power mode a fault managed power at the second voltage level when the operational state of the power receiver indicates that the power receiver requests fault managed power, and otherwise select DC power at the second voltage level.

In some aspects, the techniques described herein relate to a power transmitter, wherein the controller is configured to select fault managed power at the second voltage level based on any one of: detecting a request from the power receiver for fault managed power; receiving from a management controller associated with the power transmitter a management request for use of fault managed power; or detecting a fault managed power connector associated with the power receiver.

### Variations and Implementations

In various embodiments, control logic may be executed by the controllers (e.g., microprocessors) on each power transmitter and power receiver to enable a power transmitter and a power receiver to perform the techniques presented herein. The control logic can include instructions that, when executed, cause the controller to perform operations, which can include, but not be limited to, providing overall control operations of computing device; interacting with other entities, systems, etc. described herein; maintaining and/or interacting with stored data, information, parameters, etc. (e.g., memory element(s), storage, data structures, databases, tables, etc.); combinations thereof; and/or the like to facilitate various operations for embodiments described herein.

The programs described herein (e.g., control logic) may be identified based upon application(s) for which they are implemented in a specific embodiment. However, it should be appreciated that any particular program nomenclature herein is used merely for convenience; thus, embodiments herein should not be limited to use(s) solely described in any specific application(s) identified and/or implied by such nomenclature.

In various embodiments, any entity or apparatus as described herein may store data/information in any suitable volatile and/or non-volatile memory item (e.g., magnetic hard disk drive, solid state hard drive, semiconductor storage device, random access memory (RAM), read only memory (ROM), erasable programmable read only memory (EPROM), application specific integrated circuit (ASIC), etc.), software, logic (fixed logic, hardware logic, programmable logic, analog logic, digital logic), hardware, and/or in any other suitable component, device, element, and/or object as may be appropriate. Any of the memory items discussed herein should be construed as being encompassed within the broad term ‘memory element’. Data/information being tracked and/or sent to one or more entities as discussed herein could be provided in any database, table, register, list, cache, storage, and/or storage structure: all of which can be referenced at any suitable timeframe. Any such storage options may also be included within the broad term ‘memory element’ as used herein.

Note that in certain example implementations, operations as set forth herein may be implemented by logic encoded in one or more tangible media that is capable of storing instructions and/or digital information and may be inclusive of non-transitory tangible media and/or non- transitory computer readable storage media (e.g., embedded logic provided in: an ASIC, digital signal processing (DSP) instructions, software [potentially inclusive of object code and source code], etc.) for execution by one or more processor(s), and/or other similar machine, etc. Generally, memory element(s) and/or storage associated with the controllers of the power transmitters and power receivers can store data, software, code, instructions (e.g., processor instructions), logic, parameters, combinations thereof, and/or the like used for operations described herein. This includes memory element(s) and/or storage being able to store data, software, code, instructions (e.g., processor instructions), logic, parameters, combinations thereof, or the like that are executed to carry out operations in accordance with teachings of the present disclosure.

In some instances, software of the present embodiments may be available via a non-transitory computer useable medium (e.g., magnetic or optical mediums, magneto-optic mediums, CD-ROM, DVD, memory devices, etc.) of a stationary or portable program product apparatus, downloadable file(s), file wrapper(s), object(s), package(s), container(s), and/or the like. In some instances, non-transitory computer readable storage media may also be removable. For example, a removable hard drive may be used for memory/storage in some implementations. Other examples may include optical and magnetic disks, thumb drives, and smart cards that can be inserted and/or otherwise connected to a computing device for transfer onto another computer readable storage medium.

Embodiments described herein may include one or more networks, which can represent a series of points and/or network elements of interconnected communication paths for receiving and/or transmitting messages (e.g., packets of information) that propagate through the one or more networks. These network elements offer communicative interfaces that facilitate communications between the network elements. A network can include any number of hardware and/or software elements coupled to (and in communication with) each other through a communication medium. Such networks can include, but are not limited to, any local area network (LAN), virtual LAN (VLAN), wide area network (WAN) (e.g., the Internet), software defined WAN (SD-WAN), wireless local area (WLA) access network, wireless wide area (WWA) access network, metropolitan area network (MAN), Intranet, Extranet, virtual private network (VPN), Low Power Network (LPN), Low Power Wide Area Network (LPWAN), Machine to Machine (M2M) network, Internet of Things (IoT) network, Ethernet network/switching system, any other appropriate architecture and/or system that facilitates communications in a network environment, and/or any suitable combination thereof.

Networks through which communications propagate can use any suitable technologies for communications including wireless communications (e.g., 4G/5G/nG, IEEE 802.11 (e.g., Wi-Fi®/Wi-Fi6®), IEEE 802.16 (e.g., Worldwide Interoperability for Microwave Access (WiMAX)), Radio-Frequency Identification (RFID), Near Field Communication (NFC), Bluetooth™, mm.wave, Ultra-Wideband (UWB), etc.), and/or wired communications (e.g., T1 lines, T3 lines, digital subscriber lines (DSL), Ethernet, Fibre Channel, etc.). Generally, any suitable means of communications may be used such as electric, sound, light, infrared, and/or radio to facilitate communications through one or more networks in accordance with embodiments herein. Communications, interactions, operations, etc. as discussed for various embodiments described herein may be performed among entities that may directly or indirectly connected utilizing any algorithms, communication protocols, interfaces, etc. (proprietary and/or non-proprietary) that allow for the exchange of data and/or information.

In various example implementations, any entity or apparatus for various embodiments described herein can encompass network elements (which can include virtualized network elements, functions, etc.) such as, for example, network appliances, forwarders, routers, servers, switches, gateways, bridges, loadbalancers, firewalls, processors, modules, radio receivers/transmitters, or any other suitable device, component, element, or object operable to exchange information that facilitates or otherwise helps to facilitate various operations in a network environment as described for various embodiments herein. Note that with the examples provided herein, interaction may be described in terms of one, two, three, or four entities. However, this has been done for purposes of clarity, simplicity and example only. The examples provided should not limit the scope or inhibit the broad teachings of systems, networks, etc. described herein as potentially applied to a myriad of other architectures.

Communications in a network environment can be referred to herein as ‘messages’, ‘messaging’, ‘signaling’, ‘data’, ‘content’, ‘objects’, ‘requests’, ‘queries’, ‘responses’, ‘replies’, etc. which may be inclusive of packets. As referred to herein and in the claims, the term ‘packet’ may be used in a generic sense to include packets, frames, segments, datagrams, and/or any other generic units that may be used to transmit communications in a network environment. Generally, a packet is a formatted unit of data that can contain control or routing information (e.g., source and destination address, source and destination port, etc.) and data, which is also sometimes referred to as a ‘payload’, ‘data payload’, and variations thereof. In some embodiments, control or routing information, management information, or the like can be included in packet fields, such as within header(s) and/or trailer(s) of packets. Internet Protocol (IP) addresses discussed herein and in the claims can include any IP version 4 (IPv4) and/or IP version 6 (IPv6) addresses.

To the extent that embodiments presented herein relate to the storage of data, the embodiments may employ any number of any conventional or other databases, data stores or storage structures (e.g., files, databases, data structures, data or other repositories, etc.) to store information.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments. Note also that a module, engine, client, controller, function, logic or the like as used herein in this Specification, can be inclusive of an executable file comprising instructions that can be understood and processed on a server, computer, processor, machine, compute node, combinations thereof, or the like and may further include library modules loaded during execution, object files, system files, hardware logic, software logic, or any other executable modules.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of can be represented using the’ (s)' nomenclature (e.g., one or more element(s)).

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

What is claimed is:

1. A method performed by a power receiver, comprising:
upon powering up or upon power reset, determining a voltage type associated with power received at the power receiver from a power transmitter;
depending on the voltage type, selecting a power mode among a plurality of power modes that include fault managed power modes at different voltages and at least one non-fault managed power mode; and
entering a selected power mode based on the selecting.

2. The method of claim 1, wherein determining comprises determining whether the voltage type is a direct current (DC) voltage at a first voltage level, and further comprising:
when the voltage type is the DC voltage at the first voltage level, determining whether the power received is indicative of a pulse voltage mode fault managed power.

3. The method of claim 2, wherein when the power received is not indicative of pulse voltage mode fault managed power, selecting comprises selecting a non-fault managed power mode at the first voltage level.

4. The method of claim 2, wherein when the power received is indicative of pulse voltage mode fault managed power, further comprising:
determining whether DC pulses of the power are within a predetermined voltage range,
wherein selecting comprises selecting a fault managed power mode at the first voltage level when the DC pulses of the power are within the predetermined voltage range.

5. The method of claim 4, wherein when the DC pulses of the power are not within the predetermined voltage range, further comprising:
sending current pulses from the power receiver to the power transmitter in an attempt to negotiate a current mode power; and
determining whether the power transmitter responds to the current pulses by decreasing time between voltage “off” periods of the DC pulses,
wherein selecting comprises selecting as the selected power mode, fault managed power at a second voltage level greater than the first voltage level when the power transmitter does not decrease time between voltage “off” periods of the DC pulses in response to sending the current pulses.

6. The method of claim 5, wherein when it is determined that the power transmitter responds to the current pulses by decreasing time between voltage “off” periods of the DC pulses, further comprising:
decreasing time between “off” periods of the current pulses sent from the power receiver to the power transmitter;
determining whether the power transmitter stops sending DC voltage pulses and starts sending DC current pulses;
when it is determined that the power transmitter stops sending DC voltage pulses and starts sending DC current pulses, selecting comprises selecting as the selected power mode a fault managed power current mode; and
when it is determined that the power transmitter does not stop sending DC voltage pulses and start sending DC current pulses, selecting comprises selecting as the selected power mode, fault managed power at the second voltage level.

7. The method of claim 2, wherein when the voltage type is not a DC voltage at a first voltage level, further comprising:
determining whether the power received from the power transmitter includes voltage pulses with “off” time periods;
when the power includes voltage pulses with “off” time periods, sending current pulses from the power receiver to the power transmitter in an attempt to negotiate current mode power;
determining whether the power transmitter responds to the current pulses by decreasing time between voltage “off” periods of the voltage pulses; and
when the power transmitter does not decrease time between voltage “off” periods of the voltage pulses, selecting comprises selecting a high voltage DC power mode at a second voltage level greater than the first voltage level.

8. The method of claim 7, wherein when it is determined that the power transmitter responds to the current pulses by decreasing time between voltage “off” periods of the voltage pulses, further comprising:
decreasing time between “off” periods of the current pulses sent from the power receiver to the power transmitter;
determining whether the power transmitter stops sending voltage pulses and starts sending current pulses; and
when it is determined that the power transmitter stops sending voltage pulses and starts sending current pulses, selecting comprises selecting as the selected power mode a fault managed power current mode.

9. The method of claim 8, wherein when it is determined that the power transmitter does not stop sending voltage pulses and start sending current pulses, further comprising performing a power reset of the power receiver.

10. A method performed by a power transmitter to provide power to a power receiver, comprising:
upon powering up of the power transmitter, determining a type of an input voltage to the power transmitter;
depending at least on a type of the input voltage and an operational state of the power transmitter, selecting one of a plurality of power modes that include fault managed power modes at different voltages, at least one non-fault managed power mode and an alternating current (AC) power mode; and
transmitting power according to a selected power mode based on the selecting.

11. The method of claim 10, when the input voltage is a direct current (DC) voltage at a first voltage level:
initially transmitting DC voltage at the first voltage level; and
selecting comprises as the selected power mode a fault managed power at the first voltage level when the operational state of the power receiver indicates that the power receiver requests fault managed power, and otherwise selecting comprises selecting non-fault managed power.

12. The method of claim 11, wherein selecting comprises selecting fault managed power at the first voltage level based on any one of:
detecting a request from the power receiver for fault managed power;
receiving from a management controller associated with the power transmitter a management request for use of fault managed power; or
detecting a fault managed power connector associated with the power receiver.

13. The method of claim 10, when the input voltage is a DC voltage at a second voltage level:
initially transmitting DC voltage at a first voltage level less than the second voltage level; and
selecting comprises as the selected power mode a fault managed power at the second voltage level when the operational state of the power receiver indicates that the power receiver requests fault managed power, and otherwise selecting comprises selecting DC power at the second voltage level.

14. The method of claim 13, wherein selecting comprises selecting fault managed power at the second voltage level based on any one of:
detecting a request from the power receiver for fault managed power;
receiving from a management controller associated with the power transmitter a management request for use of fault managed power; or
detecting a fault managed power connector associated with the power receiver.

15. The method of claim 10, when the input voltage is a DC voltage at a third voltage level, selecting comprises selecting DC power at the third voltage level, and further comprising:
generating a management message indicating unmanaged power or fully managed power at the third voltage level.

16. The method of claim 10, when the input voltage is an AC voltage, selecting comprises selecting AC power, and further comprising:
generating a management message indicating unmanaged AC power or fully managed AC power.

17. A power receiver comprising:
a voltage sense circuit configured to determine a voltage type associated with power received on a cable from a power transmitter; and
a controller coupled to the voltage sense circuit, wherein the controller is configured to select a power mode among a plurality of power modes that include fault managed power modes at different voltages and at least one non-fault managed power mode, and to cause the power receiver to enter a selected power mode.

18. The power receiver of claim 17, wherein the controller is further configured to determine whether the power is indicative of a pulse voltage mode fault managed power when the voltage type is a direct current (DC) voltage at a first voltage level.

19. The power receiver of claim 18, wherein the controller is configured to select a non-fault managed power mode at the first voltage level when the power received is not indicative of pulse voltage mode fault managed power.

20. The power receiver of claim 18, wherein when the power received is indicative of pulse voltage mode fault managed power the controller is configured to:
determine whether DC pulses of the power are within a predetermined voltage range; and
select a fault managed power mode at the first voltage level when the DC pulses of the power are within the predetermined voltage range.

21. A power transmitter comprising:
a voltage sense circuit configured to sense an input voltage of input power to the power transmitter; and
a controller coupled to the voltage sense circuit, wherein the controller is configured to, depending at least on a type of the input voltage and an operational state of the power transmitter, select one of a plurality of power modes to transmit power to a power receiver, the plurality of power modes including fault managed power modes at different voltages, at least one non-fault managed power mode and an alternating current (AC) power mode, depending at least on a type of the input voltage and an operational state of the power transmitter.

22. The power transmitter of claim 21, wherein, when the input voltage is a direct current (DC) voltage at a first voltage level, the controller is configured to:
cause a DC voltage to initially be transmitted at the first voltage level; and
select as a selected power mode a fault managed power at the first voltage level when the operational state of the power receiver indicates that the power receiver requests fault managed power, and otherwise select non-fault managed power.

23. The power transmitter of claim 22, wherein the controller is configured to select fault managed power at the first voltage level based on any one of:
detecting a request from the power receiver for fault managed power;
receiving from a management controller associated with the power transmitter a management request for use of fault managed power; or
detecting a fault managed power connector associated with the power receiver.

24. The power transmitter of claim 21, wherein when the input voltage is a DC voltage at a second voltage level, the controller is configured to:
cause DC voltage to be transmitted at a first voltage level less than the second voltage level; and
select as the selected power mode a fault managed power at the second voltage level when the operational state of the power receiver indicates that the power receiver requests fault managed power, and otherwise select DC power at the second voltage level.

25. The power transmitter of claim 24, wherein the controller is configured to select fault managed power at the second voltage level based on any one of:
detecting a request from the power receiver for fault managed power;
receiving from a management controller associated with the power transmitter a management request for use of fault managed power; or
detecting a fault managed power connector associated with the power receiver.
